(19) United States
(12) Patent Application Publication
(10) Pub. No.: US 2026/0358418 A1
(43) Pub. Date: Nov. 12, 2026

(54) MODEL OF A SOFT SENSOR FOR MEASURING MECHANICAL DAMAGE, AND A SOFT SENSOR

(71) Applicant: Siemens Aktiengesellschaft, 80333 München (DE)

(72) Inventors: MARTIN BRÜCKEL, Erlangen (DE); PRANITA RAJAN PRADHAN, Fürth (DE); TIMO RIESKAMP, München (DE)

(73) Assignee: Siemens Aktiengesellschaft, 80333 München (DE)

(21) Appl. No.: 19/488,733

(22) PCT Filed: Apr. 22, 2024
(86) PCT No.: PCT/EP2024/060857

§ 371 Date: Nov. 28, 2025

(30) Foreign Application Priority Data
May 31, 2023 (EP) 23176429.1

(51) Int. Cl. G01R 31/34; G01H 1/00

(52) U.S. Cl. CPC G01R 31/34; G01H 1/003

(57) ABSTRACT

A method for measuring mechanical damage to an electric rotating machine includes receiving, via a first interface of a computing facility, acceleration sensor data measured at the electric rotating machine and magnetic field sensor data corresponding to the acceleration sensor data; determining from the magnetic field sensor data, an operating point of the electric rotating machine and acceleration sensor data corresponding to the operating point, and from the acceleration sensor data a severity of mechanical damage to a mechanical component. A model of a soft sensor which receives the magnetic field sensor data and the acceleration sensor data as input variables via a second interface of the computing facility is formed based on the magnetic field sensor data, the acceleration sensor data, the operating point and the damage severity, and outputs operating points and the damage severity as an output variable.

The present invention relates to a method for providing a model of a soft sensor, wherein the model is contained in the soft sensor, for measuring a mechanical damage to an electric rotating machine, a soft sensor with such a model and a method for measuring the mechanical damage to the electric rotating machine by means of such a soft sensor.

US 2022/011763 A1 discloses: A method for monitoring at least one machine, comprising the following: causing at least one first sensor to capture at least a first non-stationary signal from at least one machine which operates in a non-stationary manner during at least one operating period, wherein the at least one first sensor provides at least a first non-stationary output, causing at least one second sensor to capture at least a second non-stationary signal from the at least one machine during the operating period, wherein the at least one second sensor provides at least one second non-stationary output, merging the at least one first non-stationary output with the at least one second non-stationary output in order to generate a merged output, extracting at least one feature from at least one of the first and second non-stationary signals on the basis of the merged output, analyzing the at least one feature in order to establish a state of health of the at least one machine, and carrying out at least one of the following steps: repair procedure, servicing procedure and changing operating parameters of the at least one machine on the basis of the state of health that has been established by the analysis.

WO 2022/148751 A1 relates to a sensor apparatus for monitoring a rotational machine having a motor. The sensor apparatus is suitable for mounting on a surface of the rotational machinery. The sensor apparatus comprises an outer housing with an outer surface. The sensor apparatus is adapted for monitoring the state of the rotational machinery by using a magnetic field sensor which is configured for measuring a magnetic field during the rotation of the rotor, an accelerometer that is configured for measuring mechanical vibrations during the rotation of the rotor, and/or a measuring circuit which comprises a first sensor element and a second sensor element that is configured for measuring a field during the rotation of the rotor. The sensor apparatus is configured with a data processing arrangement and one or more signal units in communication with the data processing arrangement. The data processor arrangement is configured for the processing of input on the basis of measurements carried out and according to one predetermined set of rules. The sensor apparatus is configured, on the basis of the processing, to provide a merged output which gives a machine state from a plurality of machine states. The disclosure also relates to corresponding methods for monitoring rotational machines. Herein, computer programs for carrying out the method steps and a computer-readable medium for storing the computer programs are also disclosed.

In the status monitoring of electric drives, for example, rotational electric machines and their industrial applications, one of the most important measurement variables is vibration, since, provided it is measured with sufficiently good measuring technology and sufficiently close to the mechanical components, it represents a good indicator for possible errors and cases of damage. One of the examples of fault causes that can also be recognized by oscillation measurement in electric rotating machines is, primarily, bearing damage, and also other mechanical faults such as, for example, incorrect alignment of the axes or mechanical imbalances in the machine or its application, as well as loose mountings. A fundamental problem herein is that the oscillation measurement can depend upon many external factors, particularly if measurements are not made directly on the mechanical components (e.g. bearing housings). In particular, the load condition of the machine or its application has a substantial Influence on the oscillation amplitude and also on the strength of the defect frequencies in the spectrum, as also does the rotary speed.

The central problem in the assessment of the mechanical damage, for example, the damage status of a bearing or the damage severity, is that it cannot be judged purely on the basis of the occurrence of specific defect frequencies, since it has been found that these can occur even in a newly installed fault-free bearing. Similarly, by way of measurement with an external sensor, that is, a measurement not directly on the bearing housing, again, no generally applicable assessment of the severity of damage can be made on the basis of frequency strengths. In order, therefore, to make a general assessment regarding a bearing damage or other mechanical damage arising at a specific time point, the individual measurements must be put in relation to one another.

Common measuring systems for status monitoring are either employed only on a sampling basis to obtain a short-term situation overview regarding the state of health of the bearing and the mechanical components or they evaluate individual regularly transmitted high-resolution oscillation or acoustic data with respect to features of bearing damage or the damage statuses mentioned above. The evaluation for this mostly takes place on the basis of individual raw data recordings which are considered more or less independently of one another. Herein, filtering takes place usually in the frequency spectrum for the frequency portions of the mechanical rotation frequency or the known bearing damage frequencies and, from these frequency portions of the overall spectrum, an evaluation is made of the severity of a possible damage. A substantial disadvantage of most of the common systems herein is that for a precise recognition and evaluation of mechanical damage, for example, bearing damage, specific defect frequencies of the mechanical components in question (e.g. in a bearing: inner race frequency, outer race frequency, ball spin frequency, cage frequency, etc.) and thus also their geometry and their specific type and manufacturer must be known—therefore, for a bearing: bearing geometry, bearing type and manufacturer. This specific information is often no longer available after an exchange of the mechanical components and even in the case of an installed component it cannot be readily obtained without its removal.

Due to the above, a need exists for a soft sensor which can determine the severity of damage to the mechanical components with little foreknowledge of these mechanical components.

For this purpose, a method of the type mentioned above is proposed in which
via a first interface, acceleration sensor data measured at the electric rotating machine and magnetic field sensor data corresponding to the acceleration sensor data is received,
by way of a computing facility,
   from the magnetic field sensor data, an operating point of the electric rotating machine is determined, acceleration sensor data corresponding to the operating point is determined and assigned to the operating point, and from the acceleration sensor data corresponding to the operating point, a severity of the damage to a mechanical component of the electric rotating machine—a damage severity—is determined,
   on the basis of the magnetic field sensor data, the acceleration sensor data, the operating point and the damage severity, a model is formed which receives magnetic field sensor data and acceleration sensor data as input variables and outputs the damage severity as an output variable,
the model is provided via a second interface.

In other words, the present disclosure relates to a method for generating or training a soft sensor for or on a (specific) electric rotating machine.

The damage severity is therein established as a function of the time at which the acceleration sensor data has been measured. As the output variable, the model preferably provides the damage severity as a function of time-that is, a temporal trend in the damage severity.

It is self-evident that different mechanical damage severity levels can be assigned to different operating points.

In one embodiment, it can be provided that the acceleration sensor data and the magnetic field sensor data is measured with a hardware sensor contained in the soft sensor, said hardware sensor being arranged, in particular fastened, for example, externally on the machine housing. In particular, it can be provided that the hardware sensor is not arranged on the mechanical component, for example, the bearing.

In one embodiment, it can be provided that the acceleration sensor data is preprocessed. The preprocessing can comprise, for example, a correction of the time stamp assigned to the data and/or a filtering according to particular frequencies. Bearing damage frequencies can lie, for example, in a range between 3 kHz and 8 KHz.

In one embodiment, it can be provided that the acceleration sensor data and the magnetic field sensor data is measured via a large number of preferably disjoint or non-overlapping time intervals of a particular length that is preferably 5 to 10 seconds. Such individual measurements can take place at different time points, for example, 2-3 times per day, on a plurality of successive days, 10 to 30, in particular 15, days. Thereby, a large number of raw data fragments is produced, each fragment containing a, for example, 10-second long individual measurement. The fragments are preferably high-resolution.

The damage severity can therein be determined for individual, preferably for all, the acceleration sensor data fragments. For example, the damage severity calculated for a single acceleration sensor data fragment corresponds to one damage severity data point. A plurality of such damage severity data points can form the damage severity as a function of time, that is, its temporal development or its trend.

In other words, the acceleration sensor data is collected, preferably over a relatively long time period.

It can thus be provided, in one embodiment, that the acceleration sensor data and the magnetic field sensor data comprises a large number of data fragments, wherein each acceleration sensor data fragment is placed in relation (and thus corresponds) to exactly one magnetic field sensor data fragment.

Therein, the measuring intervals for the acceleration sensor data and for the magnetic field sensor data do not have to be identical. That is, the acceleration and magnetic field sensor data fragments can be configured differently have different sizes, contain different data quantities, etc.

For example, the acceleration sensor data at 6.6 kHz and 6 seconds long can contain vibration values measured in the X, Y and Z-directions. A magnetic field measurement can take, for example, two minutes at 500 Hz.

In one embodiment, it can be provided that by way of a computing facility, from the acceleration sensor data, one or more damage parameters are determined and from the one or more damage parameters, the damage severity is determined.

Preferably, the model is configured to output the damage parameter(s) as output variable(s).

It can be suitable therein if the one or more damage parameters characterize a portion and/or a strength of cyclostationary frequencies, i.e. the amplitude of the signals representing the cyclostationary frequency in the, for example preprocessed, acceleration sensor data, preferably in the respective acceleration sensor data fragments.

In one embodiment, it can be provided that the one or more damage parameters can be calculated with the aid of an extended envelope spectrum (see Jérôme Antoni, Ge Xin, N. Hamzaoui: Fast computation of the spectral correlation). By way of the use of the extended envelope spectrum, it is possible to recognize reliably cyclostationary frequencies and thus possible damage frequencies, even at a low signal-to-noise ratio. This is, above all, important for external hardware sensors since thereby, in general, a higher noise level is observed and a larger number of external factors acts upon the signal on the transmission route of the damage signal from the source to the sensor, for example, additively, and thus causes a disturbance.

It has been recognized that the strength of cyclostationary frequencies is an indicator for mechanical defect frequencies, although this does not have to be known in detail, rather only the approximate frequency range of its occurrence in the specific measuring system (amplified by the resonance frequency of the measurement setup and thereby stronger in the specific frequency range, also the known frequency range of the occurrence of specific damage according to the general state of knowledge, for example, for bearing damage, between 3 and 8 kHz).

In one embodiment, it can be provided that the acceleration sensor data is filtered, for example, by means of high-pass or low-pass filtering. High-pass filtering can be particularly suitable for the measurement of bearing damage.

Filtering according to cyclostationary frequencies can also increase the signal-to-noise ratio, since the noise is not cyclostationary and is filtered out during filtering.

In one embodiment, it can be provided that the acceleration sensor data comprises vibration values, preferably vibration values in three mutually orthogonal directions.

In one embodiment, it can be provided that, on the basis of the magnetic field sensor data, an operating point model of the electric rotating machine is generated, wherein the operating point model characterizes one or more operating points by way of rotary speed ranges assigned to the operating points, wherein, in the operating point model, different rotary speed ranges are assigned to different operating points.

The rotary speed ranges can be determined from the magnetic field sensor data.

The creation of the operating point model can take place, for example, in the cloud.

In one embodiment, it can be provided that the operating point model of the electric rotating machine is generated from the (regularly) measured rotary speed and torque values measured and transmitted, for example, to the cloud and collected by a cloud application.

It can be suitable if the different rotary speed ranges are determined from the magnetic field sensor data and, on the basis of the different rotary speed ranges, the different operating points are defined.

With regard to the rotary speed ranges, a distinction between the most frequent operating points can be made. For this purpose, for example, a clustering algorithm can be used which makes this distinction and creates the operating point model.

In one embodiment, it can be provided that the acceleration sensor data corresponding to the respective operating point is determined on the basis of the operating point model. Subsequently, the acceleration sensor data can be assigned to the respective operating point.

Therein, the acceleration sensor data, preferably all the collected acceleration sensor raw data recordings are assigned on the basis of their rotary speed or their torque to one of the recognized operating points.

Therein, an association on the basis of the distance (e.g. Euclidian distance) to the nearest centroid of one of the operating point clusters takes place, preferably for raw data recordings not unambiguously situated within a cluster.

Following the association of the acceleration sensor data with the respective operating points, wherein preferably each acceleration sensor data recording is assigned to one of the determined operating points as described, for example, above, the (preferably all) acceleration sensor data raw data recordings and the damage severity and preferably the damage KPIs calculated therefrom can each be distinguished according to their operating point.

In one embodiment, it can be provided that the model is updated making use of further measured acceleration sensor and magnetic field sensor data, wherein changes to the damage severity (brought about through this updating) are tracked and are stored in the model. An updating can take place, for example, each month during each servicing operation or suchlike.

In particular, the model can comprise all the past corresponding raw data fragments and the corresponding damage severity, for example, in the form of damage KPIs, for example, since the start of the data recording or since the last servicing interval (e.g. bearing change).

This updating preferably takes place for all operating points and all damage parameters.

The model therefore comprises, preferably for each operating point and thus for the associated damage severity calculated from the raw data fragments, for example, in the form of damage KPIs, as a function of time. In other words, the model enables a trend monitoring for the damage severity. The damage severity is associated, for example, with the cyclostationarity, the strength of which can be used for quantifying the damage.

It is advantageous therein that the model assesses the damage severity principally not on the basis of one value, but on the basis of a temporal development.

In other words, the model can be configured as a trend model or a trend recognition model.

For example, the model can contain an upper limit value for the damage severity and preferably for the respective damage KPIs.

In one embodiment, it can be suitable if for the, preferably for each, operating point, a trend recognition takes place for the damage severity assigned to the operating point, preferably by means of a statistical model, for example, an ARIMA (autoregressive integrated moving average) model. By this means, the previous trend of the damage severity can be modeled more exactly. If, for example, the strength of the frequencies becomes stronger, this is an indication that the state of health of the electric rotating machine has worsened. From this, notifications (e.g. an alarm) to the user can take place earlier and measures for fault prevention (servicing work such as a bearing change) can be carried out sooner than with the aforementioned exceeding of a limit value.

In one embodiment, it can be provided that from the changes, a remaining lifetime of the mechanical component of the electric rotating machine is determined.

In other words, from the temporal development/tendency of specific frequency portions over a relatively long time period, it is made possible to draw conclusions regarding the severity of a damage as a function of time and/or the approximate remaining lifetime of a mechanical component, e.g. a bearing.

Account is taken of the aforementioned need also with a method for providing a soft sensor for measuring a mechanical damage to an electric rotating machine, wherein in the method, a hardware sensor of the soft sensor is provided which is intended for measuring the acceleration sensor data and the magnetic field sensor data corresponding to the acceleration sensor data on the electric rotating machine, for example, on the machine housing, and a model of the soft sensor as described above is provided.

Furthermore, account is taken of the need with a soft sensor for measuring a mechanical damage to an electric rotating machine, wherein the soft sensor comprises: a hardware sensor, wherein the hardware sensor is constructed and configured to measure acceleration sensor data and magnetic field sensor data corresponding to the acceleration sensor data at an electric rotating machine, and a model which is provided as described above,

A soft sensor of this type forms an analysis system for recognizing and evaluating the severity of a mechanical damage caused to a mechanical component, in particular a bearing damage.

In addition, the need is taken into account with a method for measuring a mechanical damage to an electric rotating machine by means of the aforementioned soft sensor, wherein with the hardware sensor, acceleration sensor data and magnetic field sensor data corresponding to the acceleration sensor data is measured, for example, in the form of fragments and is fed to the model, from the acceleration sensor data and magnetic field sensor data, the model determines a severity of the damage to a mechanical component of the electric rotating machine.

In one embodiment, it can be provided that the model determines a damage severity as a function of time from the measured data and compares it with the “normal” damage severity available in the model. The “normal” or non-critical damage severity can be characterized, for example, by a limit value or by a trend that has been determined from the measurement data on creation of the model (see above). On the basis of the comparison, notifications such as alarms that are accompanied by further information to the user (context of the notification or suchlike) can be output.

If, for example, the limit value is exceeded multiple times (e.g. on one day), an alarm is output. If a limit value is exceeded significantly more on the subsequent day, the state is worsening faster and is becoming more critical.

If the trend of the damage severity has become steeper, the model can check whether this new tendency is still within a predetermined or predeterminable tolerance. Dependent upon the deviation from the previous tendency within each operating point, the severity of the deterioration of the mechanical damage pattern, for example, of the bearing status can be determined, wherein in general, a steeper rise indicates a more rapid deterioration than in the previous trend and thereby a greater criticality (servicing operations, for example, bearing change needed urgently) and a flatter rise indicates a slower deterioration and thus a lower criticality. The result of this evaluation of the damage severity relative to the previous trend can be communicated to the user, for example, via a status change in the form of a set of traffic lights in a dashboard (e.g. the traffic lights jump from green to yellow to red if the trend is very steep) and is preferably used for updating the model. Optionally, for example, the respective urgency of relevant servicing measures (e.g. bearing change needed within a few weeks or months) can simultaneously be notified to the user.

In summary, by way of a regular recording of raw data fragments (e.g. every day, for 10 seconds) and focusing on the trend or the tendency of the calculated damage severity or the damage indicators (KPIs) rather than the absolute value, a more robust determination of the damage severity is possible than with conventional measuring methods and evaluating processes, such as, for example, in the extreme case, with random sampling testing, which methods are often unable to guarantee any comparability in their course over time or are anyway only carried out once. In addition, the evaluation of the trend in comparison with the previous trend of the deterioration permits an improved prognosis of a possible failure and therefore of the remaining lifespan, for example, in the case of a bearing damage.

An advantageous embodiment is the following:

A feature extraction is, for example: sensor data is observed within a particular range, for example, by means of bandpass filtering. Thus peaks, and peaks at particular frequencies, can be analyzed and ratios observed. These can be indicators of damage.

Fusion advantageously means placing the acceleration sensor data into relation with magnetic field sensor data. Herein, a bringing together of a time series of acceleration sensor data with a time series of the magnetic field sensor data to a common time series is advantageous.

An embodiment according to which the feature extraction for the acceleration sensor data is initially carried out separately is advantageous. Also advantageously, a fusion takes place of the extracted data with the magnetic field sensor data.

In other words, this can be described in this way: Preferably, the feature extraction is carried out independently on the individual sensor signals and only thereafter, the magnetic field and the extracted feature vectors are merged.

The invention further relates to a computer-implemented method for providing a model of a soft sensor for measuring mechanical damage to an electric rotating machine.

The invention further relates to a computer program product comprising commands which, on execution of the program by a computing facility, cause it to carry out the steps of the method.

Further features, properties and advantages of the present invention are disclosed in the following description, making reference to the accompanying drawings. It is shown schematically in:

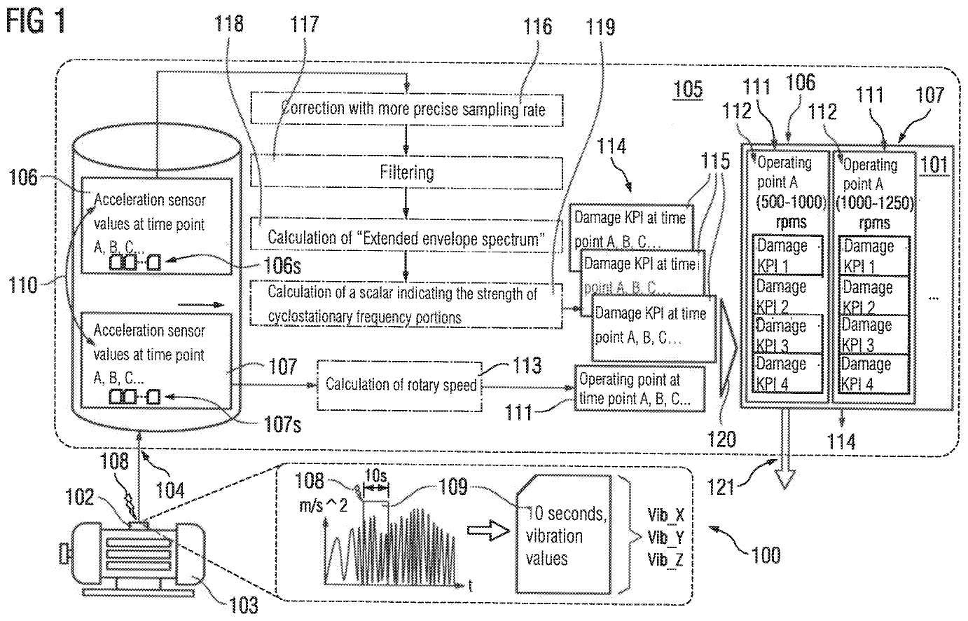

FIG. 1 a sequence of a method for providing a model of a soft sensor, and

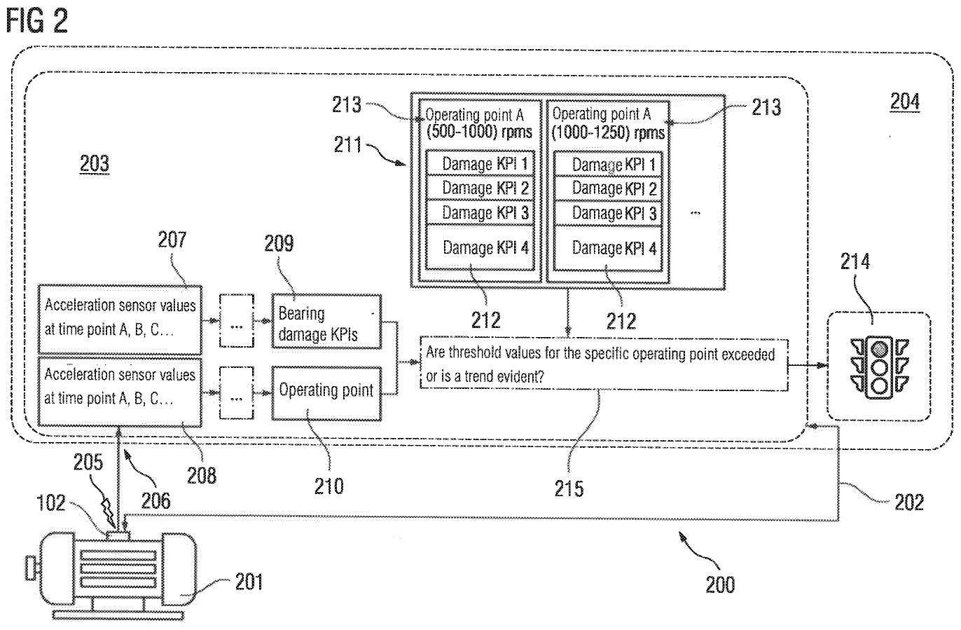

FIG. 2 a sequence of a method for measuring a bearing damage in an electric rotating machine.

In the exemplary embodiments and drawings, the same or similarly acting elements may each be provided with the same reference signs. The elements shown and their size relationships to one another are, in principle, not to be regarded as being to scale, rather individual elements may be represented dimensioned relatively larger for better illustration and/or better understanding.

FIG. 1 shows schematically an exemplary sequence of a method 100 for providing a model 101 of a soft sensor which, in addition to the model 101, comprises a hardware sensor 102.

The present soft sensor is configured to measure a mechanical damage to an electric motor 103 or one or more of its components.

This damage can affect, for example, the bearing, faulty alignment (e.g. in the axle/shaft), mechanical eccentricity or loose mounting of the entire motor 103 on the base—a loose base being known as a “soft, or loose, foot”.

The creation of the model 101 begins with acceleration sensor data 106 and magnetic field sensor data 107 corresponding to the acceleration sensor data 106 being received, for example, via a first interface 104 of a computing facility 105.

The computing facility 105 is configured, for example, as a cloud infrastructure and can comprise a plurality of cooperating computing units mutually connected in a network and coordinated with one another.

FIG. 1 shows that the hardware sensor 102 is mounted on the electric motor 103, is fastened externally on the motor housing and measures the acceleration sensor data 106 and the magnetic field sensor data 107. The acceleration sensor data 106 can comprise vibration values of, for example, the electric motor bearing in the X-, Y- and Z-directions, Vib_X, Vib_Y and Vib Z

The hardware sensor 102 preferably has a communication unit and is able to be wirelessly actuated, for example, by the cloud infrastructure 105. In particular, the hardware sensor 102 is configured as an IIoT device.

The measurement and the upload of the acceleration sensor data 106 and the magnetic field sensor data 107 can take place with a trigger 108. In principle, the trigger 108 can be actuated at different time points, for example, multiple times (e.g. 2-3 times) per day. A measurement that can contain a plurality of individual measurements can last, in total, multiple days, for example 10, 15, 30 days or longer and can comprise a large number of triggered measuring portions or individual measurements 109. An individual measuring portion 109 can last, for example, a few seconds, for example, preferably 5 to 10 seconds.

In particular, the acceleration sensor data 106 can comprise the fragments 106s with vibration values in the X, Y and Z-directions, that have been measured at 6.6 kHz for 6 seconds.

A magnetic field measurement can take place, for example, over two minutes at a frequency of 500 Hz.

The measurement data (the acceleration sensor data 106 and the magnetic field sensor data 107) can thus contain a large number of data fragments 106s, 107s.

Preferably, by way of the computing facility 105, exactly one magnetic field sensor data fragment 107s is placed in relation to each acceleration sensor data fragment 106s. In this way, a (temporal) correspondence 110 is established between the acceleration sensor data 106 and the magnetic field sensor data 107.

From the magnetic field sensor data 107, the computing facility 105 determines operating points 111 of the electric motor 103, so that the operating point 111 is known at a time point A, B, C, . . . that can be determined from the measurement data. Therein, the computing facility 105 can assign the respective operating points 111, for example, to predetermined rotary speed ranges 112. This can be determined on the basis of motor parameters transmitted regularly, for example, on each trigger 108, such as for example, the rotary speed and/or torque of the electric motor 103, wherein the motor parameters are determined by way of the hardware sensor 102. Therein, the hardware sensor 102 can be configured to determine rotary speeds and/or torques from the magnetic field sensor data 107.

Preferably, the operating point 111 is determined for each magnetic field sensor data fragment 107s.

The operating points 111 determined can be grouped together in an operating point model of the electric motor 103. The operating point model therein characterizes the operating points 111 by the rotary speed ranges 112 assigned to the operating points 111. In the operating point model, different operating points 111 can be assigned to different rotary speed ranges 112.

For example, the different rotary speed ranges 112 can be determined from the magnetic field sensor data 107. This can be carried out 113 by way of the computing facility 105 or can be calculated in the hardware sensor 102. Subsequently, on the basis of the different rotary speed ranges 112, the different operating points 111 can be defined.

The operating point model can be created, for example, by means of a clustering algorithm which, with regard to the rotary speed ranges 112, enables a distinction of the most frequent operating points 111 to be made. Regarded as the operating point 111 in the context of an operating point model formed by means of a clustering algorithm is an operating point cluster which comprises a plurality or even a large number of operating points 111 lying within the same rotary speed range 112.

The computing facility 105 determines the acceleration sensor data 106 corresponding to each operating point and assigns it to the respective operating point 111. This can also take place on the basis of the rotary speed or the torque that is assigned to the acceleration sensor data 106.

In other words, all the collected raw data recordings 106, 107 are assigned on the basis of their rotary speed or their torque to one of the recognized operating points 111. Therein, the rotary speed or the torque can serve as a form of data label.

The determination of the acceleration sensor data 106 corresponding to the respective operating points (and the assignment) can take place on the basis of the operating point model. This can take place on the basis of a distance, for example, a Euclidian distance to the nearest centroid of one of the operating point clusters.

From the acceleration sensor data 106 corresponding to the respective operating point 111, the computing facility 105 calculates a severity of the damage to a mechanical component of the motor-that is, a damage severity 114.

The damage severity 114 of each operating point 111 can be determined, for example, in the form of one or more damage parameters 115 or damage KPIs (Key Performance Indicators).

In a suitable embodiment of the method, one or more damage parameters 115 can characterize a portion and/or a strength of cyclostationary frequencies in the acceleration sensor data 106, preferably in the respective acceleration sensor data fragments 106s. The use of the cyclostationary frequencies is based upon the recognition that the defect frequencies, in particular, for a bearing damage, are cyclostationary.

The damage parameters 115 can be calculated, for example, with the aid of an extended envelope spectrum.

FIG. 1 makes it clear that the determination of the damage KPIs 115 from the acceleration sensor data fragments 106s can, in principle, comprise four steps.

The correction 116 of the acceleration sensor data 106 or the acceleration sensor data fragments 106s with a more accurate sampling rate or the correction of the time stamps by way of a corrected sampling rate and the filtering 117 therein form the steps of a data preprocessing. The filtering 117 can be a high frequency or a low frequency filtering and is, in principle, task-specific. For the determination of a bearing damage, for example, high-pass filtering is suitable since the relevant frequencies are within the corresponding region of the spectrum.

It can be suitable to filter the acceleration sensor data 106 according to the cyclostationary frequencies described above. By this means, the noise can be filtered out better and, at the same time, the signal-to-noise ratio can be improved.

Furthermore, cyclostationary effects are dependent upon the rotary speed, i.e. more or less strong. For example, the higher the rotary speed is, the stronger the signal is (cyclostationary frequency). In other words, the cyclostationary frequencies have an operating point-dependent behavior.

For the acceleration sensor data 106 preprocessed as described above, an extended envelope spectrum can be calculated 118.

From the extended envelope spectrum, a calculation 119 of a scalar can be carried out which indicates the strength of the cyclostationary frequency portions.

The calculated scalars serve as damage KPIs for each operating point 111.

In summary, the model 101 is formed 120 on the basis of the magnetic field sensor data 106, the acceleration sensor data 107, the operating point 111 and the damage severity 114. This means, in particular, that the steps described above that are performed by the computing facility 105 can be Implemented in the model 101 in the form of machine-executable commands (e.g. computer code) so that the model 101 can be carried out by any desired computing facility in that it executes the commands contained in the model 101.

The model 101 contains magnetic field sensor and acceleration sensor data 106, 107 as input variables and outputs the damage severity 114 as an output variable.

It is self-evident that different operating points 111 can be assigned to different mechanical damage severity levels 114.

FIG. 1 also reveals that if the damage severity 114 is characterized by way of the damage parameters 115, the model 101 can be configured so that it outputs, for example, the damage severity in the form of the damage parameters 115 assigned to the respective operating point 111 as an output variable.

The model 101 is provided via a second interface 120 of the computing facility 105.

The model 101 can be updated using further measured acceleration sensor data and magnetic field sensor data (not shown here).

The changes in the damage severity 114 assigned to the operating point 111 brought about by this updating can thus be tracked and stored in the model 101. It can be useful to track the changes for all the operating points 111 and for all the damage KPIs 115.

The updating of the model 101 can take place at regular time intervals (e.g. once per month). In principle, however, the regularity can depend upon an empirical value which contains information regarding the rate of the deterioration of the state of the mechanical components.

For each operating point 111, a trend recognition can take place at the relevant damage severity 114. This can take place, for example, by means of a statistical model, for example, an ARIMA model.

From the changes and, in particular, from the trend of the damage severity 114 assigned to the operating point 111, a remaining lifespan of the mechanical components of the electric motor can be determined.

In other words, the updated model describes the previous trend of the calculated damage KPls 115 within each recognized operating point 111 and thus does not depend primarily on the absolute value of the damage KPIs 115, rather mainly on its temporal development.

It is therefore possible with the model 101 to draw conclusions from the temporal development/tendency of specific frequency portions over a relatively long time period, regarding the severity of a damage and, in particular, the approximate remaining lifetime of the mechanical component, for example, the bearing and the mechanical components.

The method described in relation to FIG. 1 can be regarded as a method for training or for generating a soft sensor for a specific electric motor 103. The phase of generating the model 101 therein represents a phase of learning about the electric motor 103 and, in general, an electric rotating machine. In this regard, the model describes the normal behavior of the electric motor 103.

The model 101 can also be given limits for the damage severity 114. The limits can be configured as one or more statistical variables that are calculated from the damage severity 114, for example, a maximum (or another upper limit value), a standard deviation, etc.

FIG. 2 shows schematically an exemplary sequence of a method 200 for measuring a bearing damage in an electric rotating machine 201.

A soft sensor 202 is thus assigned to the machine 201, wherein a hardware sensor of the soft sensor 202 can be configured as the hardware sensor 102 of FIG. 1. The hardware sensor 102 is preferably mounted on the machine 201 in the same manner as on the electric motor 103.

Furthermore, the soft sensor 202 has a model 203. The model 203 was generated according to the steps described in relation to FIG. 1 with the distinction that the measurements were carried out on the machine 201, the filtering 117 was configured as a high-pass filtering in order to take account of the position of the bearing damage frequencies (e.g. 3-8 kHz) and the damage KPIs 115 are therefore bearing damage KPIs.

The model 203 is stored in a computing facility 204 which carries out the model 203. It is self-evident that in the described method according to FIG. 2, the computing facility 105 of FIG. 1 can also be used.

In the method, deviations from the normal state of the bearing, which is described in the model 203, are recognized and assessed.

The hardware sensor 102 measures acceleration sensor data and magnetic field sensor data at the electric rotating machine 201. The measurement can be initiated, for example, by way of a trigger.

The modalities of the measurement carried out are preferably the same as for the measurement described in relation to FIG. 1—duration of a single measurement (e.g. 10 seconds), their frequency, etc.

The acceleration sensor data and the magnetic field sensor data is transferred (preferably in the form of data fragments) by wire or wirelessly to the computing facility 204 and is received by the computing facility at the first interface 206.

The model 203 processes the acceleration sensor data fragments 207 and the magnetic field sensor data fragments 208 as described for the acceleration sensor data 106 and the magnetic field sensor data 107 of FIG. 1.

From the acceleration sensor data fragments 207, therefore, bearing damage KPIs 209, and from the magnetic field sensor data fragments 208, the respective operating point 210 are determined. This preferably takes place, as described above, via a determination of rotary speed ranges and by way of clusters of the operating points according to the rotary speed ranges.

It is self-evident that the (newly determined) bearing damage KPIs 209 can be used to update the model 203.

The model 203 then carries out a comparison with the data 211 that has been collected during the phase of learning about the machine 201 and, in this regard describes the normal state of the bearing.

The model 203 can, for example, only carry out the comparison on the basis of an upper limit value calculation for the particular bearing damage KPI 212 present in the model 203.

If, in the model 203, corresponding trends are available for the bearing damage KPIs 212 stored in the model 203, said trends having been calculated as described above, for example, with the aid of the ARIMA model, the model 203 can use the same statistical evaluation (e.g. the ARIMA model) to determine deviations from the previous trends.

Dependent upon the deviation from the previous trends within an operating point 213 stored in the model 203 and corresponding to the determined operating point 210, the model 203 can determine the severity of the deterioration of the bearing status.

Therein, a steeper rise indicates a more rapid deterioration than in the previous trend and thereby a greater criticality (e.g. servicing operations, for example, bearing change, needed urgently). A flatter rise, however, indicates a slower deterioration and thus a lower criticality.

The result of this evaluation of the bearing damage KPIs 209 calculated from the measurement data 207, 208 in relation to the previous trend can be communicated by the model 203 to a user. For this purpose, the model 203 can use the computing facility 204 which can comprise, for example, a display apparatus 214. Therein, the model 203 can, for example, check 215 whether particular predetermined threshold values for the specific operating point 210 are exceeded or whether a trend is evident.

For example, the model 203 can cause the computing facility 204 to generate a signal which leads to the display of a status change in the form of a set of traffic lights in a dashboard on the display apparatus 214. The set of traffic lights jumps, for example, from green to yellow or to red given a very steep increase in the trend. At the same time, the model 203 can cause the computing facility 204 to generate a further signal which is used to notify the user of the respective urgency of corresponding servicing measures (e.g. bearing change needed within a few weeks or months). It is self-evident that this information (traffic lights and indication of urgency) can be contained within the same signal.

The result of this evaluation of the bearing damage KPIs 209 calculated from the measurement data 207, 208 in relation to the previous trend can also be used to update the model 203.

The object of this description lies purely in providing illustrative examples and to state further advantages and peculiarities of this invention. It cannot therefore be interpreted as a restriction of the scope of use of the invention or of the patent rights asserted in the claims. In particular, the features disclosed in relation to the method described here can usefully be utilized for developing the sensors described herein and vice versa.

1.-17. (canceled)

18. A method for measuring mechanical damage to an electric rotating machine, the method comprising:
receiving, via a first interface of a computing facility, acceleration sensor data measured at the electric rotating machine and magnetic field sensor data corresponding to the acceleration sensor data,
determining with computing facility
from the magnetic field sensor data, an operating point of the electric rotating machine,
acceleration sensor data corresponding to the operating point and assigned to the operating point, and
from the acceleration sensor data corresponding to the operating point, a damage severity of the mechanical damage to a mechanical component of the electric rotating machine, and
forming based on the magnetic field sensor data, the acceleration sensor data, the operating point and the damage severity, a model of a soft sensor, which model is contained within the soft sensor and is provided via a second interface of the computing facility, the model receiving the magnetic field sensor data and the acceleration sensor data as input variables and outputting operating points and the damage severity as an output variable.

19. The method of claim 18, further comprising measuring the acceleration sensor data and the magnetic field sensor data with a hardware sensor contained in the soft sensor.

20. The method of claim 18, further comprising measuring the acceleration sensor data and the magnetic field sensor data over several time intervals having a duration of 5 to 10 seconds.

21. The method of claim 20, wherein the acceleration sensor data and the magnetic field sensor data each comprise a plurality of data fragments, with exactly one magnetic field sensor data fragment corresponding to exactly one acceleration sensor data fragment.

22. The method of claim 18, further comprising:
determining, with the computing facility, from the acceleration sensor data one or more damage parameters and from the one or more damage parameters the damage severity, and
outputting the one or more damage parameters as output variables of the model.

23. The method of claim 22, wherein the one or more damage parameters characterize a portion or a strength of cyclostationary frequencies in the acceleration sensor data.

24. The method of claim 18, further comprising generating based on the magnetic field sensor data an operating point model of the electric rotating machine, wherein the operating point model characterizes one or more operating points by rotary speed ranges assigned to the operating points, with different rotary speed ranges in the operating point model assigned to different operating points.

25. The method of claim 24, wherein the different rotary speed ranges are determined from the magnetic field sensor data and the different operating points are defined based on the different rotary speed ranges,.

26. The method of claim 24, wherein the acceleration sensor data corresponding to each operating point are determined based on the operating point model.

27. The method of claims 18, further comprising:
updating the model based on further measured acceleration sensor and magnetic field sensor data, and
tracking changes to the damage severity and storing the changes in the model.

28. The method of claim 27, further comprising identifying for the operating point a trend for the damage severity assigned to the operating point by means of a statistical model.

29. The method of claim 28, wherein the statistical model is an autoregressive integrated moving average (ARIMA) model.

30. The method of claim 27, further comprising determining from the changes a remaining lifetime of the mechanical component of the electric rotating machine.

31. A method for measuring mechanical damage to an electric rotating machine, the method comprising:
providing a hardware sensor of a soft sensor for measuring acceleration sensor data and magnetic field sensor data corresponding to the acceleration sensor data at the electric rotating machine, and
providing a model of the soft sensor as set forth in claim 18.

32. A soft sensor for measuring mechanical damage to an electric rotating machine, comprising
a hardware sensor constructed and configured for measuring acceleration sensor data and magnetic field sensor data corresponding to the acceleration sensor data at the electric rotating machine, and
a model of the soft sensor as set forth in claim 18.

33. A method for measuring mechanical damage to an electric rotating machine by means of a soft sensor comprising a hardware sensor constructed and configured for measuring acceleration sensor data and magnetic field sensor data corresponding to the acceleration sensor data at the electric rotating machine, and a model of the soft sensor as set forth in claim 18, the method comprising:
measuring with the hardware sensor the acceleration sensor data and the magnetic field sensor data corresponding to the acceleration sensor data and is feeding the acceleration sensor data and the magnetic field sensor data to the model, and
determining with the model, from the acceleration sensor data and the magnetic field sensor data, a severity of damage to a mechanical component of the electric rotating machine.

34. A computer-implemented method for providing a model of a soft sensor for measuring mechanical damage to an electric rotating machine, comprising the method steps as set forth in claim 18.

35. A computer program product comprising computer commands embodied on a non-volatile computer-readable medium, wherein the computer commands when read into a memory of a computer facility and executed by a processor of the computing facility, cause the computing facility to carry out the steps of the method set forth in claims 18.
